(19) United States
(12) Patent Application Publication
(10) Pub. No.: US 2011/0036499 A1
(43) Pub. Date: Feb. 17, 2011

(54) SUBSTRATE TREATMENT APPARATUS

(75) Inventors: Jung-Rak LEE, Gyeonggi-do (KR); Myung-Gon SONG, Jeollanam-do (KR); Jae-Chul DO, Daegu (KR); Bu-Il JEON, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/702,188

(22) Filed: Feb. 8, 2010

(30) Foreign Application Priority Data
Aug. 17, 2009 (KR) 10-2009-0075927

(51) Int. Cl. C23C 16/513; H01L 21/3065

(52) U.S. Cl. 156/345.48; 118/723 I

(57) ABSTRACT

A substrate treatment apparatus includes a process chamber providing a reaction region and including a body and a lid, the lid having a plurality of openings, a plurality of insulating plates sealing the plurality of openings, respectively, a plurality of antennas over the plurality of insulating plates, respectively, a gas injection unit over the lid and the plurality of insulating plates, and a substrate holding unit in the reaction region, wherein a substrate is disposed on the substrate holding unit.

The invention claims the benefit of Korean Patent Applications No. 10-2009-0075927 filed on Aug. 17, 2009, which is hereby incorporated by references.

### BACKGROUND OF THE INVENTION

1. Field of the Invention

The present invention relates to a substrate treatment apparatus, and more particularly, to a substrate treatment apparatus having uniform plasma.

2. Discussion of the Related Art

In general, a semiconductor device, a display device or a thin film solar cell is fabricated through a deposition process for depositing a thin film on a substrate, a photolithography process for exposing or covering a selected area of the thin film using a photosensitive material, and an etching process for patterning the selected area of the thin film. Among the processes, the deposition process and the etching process are performed in a substrate treatment apparatus, which is set up with optimum conditions.

Substrate treatment apparatuses used in the deposition and etching processes are classified into an inductively coupled plasma (ICP) type and a capacitively coupled plasma (CCP) type according to a plasma-generating method. In general, the ICP type is utilized for reactive ion etching (RIB) and plasma enhanced chemical vapor deposition (PECVD) apparatuses, and the CCP type is utilized for etching and deposition apparatuses using high density plasma (HDP) etching. The ICP type and the CCP type are selectively used because they have different principles in generating plasma and have advantages and disadvantages.

FIG. 1 is a schematic view of illustrating a substrate treatment apparatus using inductively coupled plasma (ICP) according to the related art.

In FIG. 1, a substrate treatment apparatus 10 includes a process chamber 12, an antenna 14, a gas supply line 16, a substrate holder 20, and an outlet 24. The process chamber 12 provides a reaction space and includes a lid 12a and a body 12b. The antenna 14 is located on the lid 12a. The gas supply line 16 provides source gases into the reaction space. The substrate holder 20 is located in a lower portion of the reaction space, and a substrate 18 is disposed on the substrate holder 20. Reaction gases and by-products in the reaction space are discharged through the outlet 22. The antenna 14 is connected to a radio frequency (RF) power source 24, and a matching unit 26 for adjusting impedance is set up between the antenna 14 and the RF power source 24.

In the substrate treatment apparatus 10 using the ICP, the antenna 14 having a coil shape is disposed on the lid 12a, and an RF power from the RF power source 24 is applied to the antenna, thereby generating an induced electric field around the antenna 14. A surface of the antenna 14 is alternately charged with positive charges and negative charges due to the RF power applied from the RF power source 24, and thus an induced magnetic field is generated. The lid 12a, on which the antenna 14 is disposed, is formed of a dielectric substance so that the induced magnetic field generated around the antenna 14 permeates into the process chamber 12 of a vacuum state.

In the substrate treatment apparatus 10, the gas supply line 16 is set up to pass through a central portion of the lid 12a. The source gases are supplied to the reaction space through the gas supply line 16. The RF power from the RF power source 24 is applied to the antenna 14. The source gases, which are supplied through the gas supply line 16, are activated or ionized and then are provided to the substrate 18. Accordingly, a substrate treating process that a thin film is deposited on the substrate 18 or a thin film on the substrate 18 is etched is performed.

By the way, since the source gases are supplied at the center of the lid 12a by the gas supply line 16, a peripheral portion of the reaction space has relative low density of the source gases as compared to a central portion of the reaction space. Therefore, a density of plasma in the peripheral portion of the reaction space is lower than the central portion of the reaction space due to the density difference of the source gases, and thus it is difficult to uniformly treat the substrate.

### SUMMARY OF THE INVENTION

Accordingly, the present invention is directed to a substrate treatment apparatus that uniformly provides process gases to a reaction region.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a substrate treatment apparatus includes a process chamber providing a reaction region and including a body and a lid, the lid having a plurality of openings, a plurality of insulating plates sealing the plurality of openings, respectively, a plurality of antennas over the plurality of insulating plates, respectively, a gas injection unit over the lid and the plurality of insulating plates, and a substrate holding unit in the reaction region, wherein a substrate is disposed on the substrate holding unit.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic view of illustrating a substrate treatment apparatus using inductively coupled plasma (ICP) according to the related art;

FIG. 2 is a schematic view of illustrating a substrate treatment apparatus using inductively coupled plasma (ICP) according to an exemplary embodiment of the present invention;

FIG. 3 is a view of enlarging the portion “A” of FIG. 2;

FIG. 4 is a perspective view of an upper part of a lid according to an exemplary embodiment of the present invention; and

FIG. 5 is a plan view of a lid facing a substrate holder according to an exemplary embodiment of the present invention.

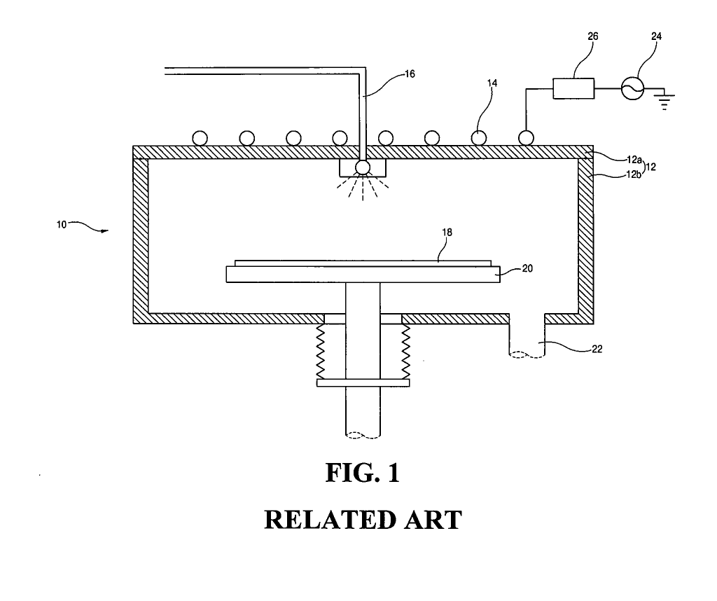

### DETAILED DESCRIPTION OF THE PREFERRED EMBODIMENTS

Reference will now be made in detail to the preferred exemplary embodiments, examples of which are illustrated in the accompanying drawings.

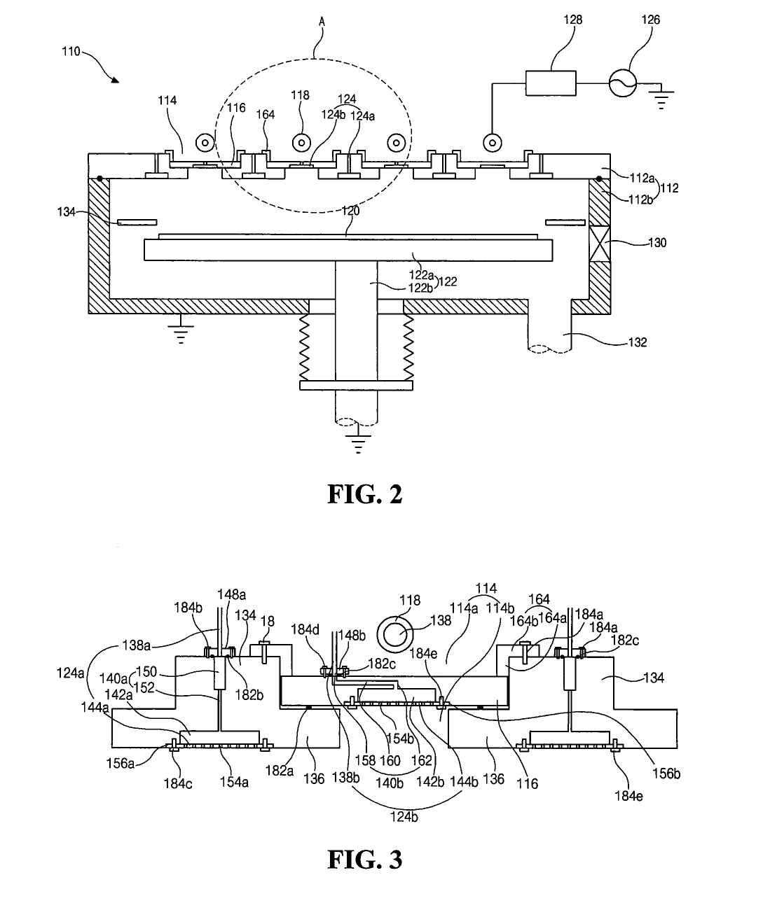

FIG. 2 is a schematic view of illustrating a substrate treatment apparatus using inductively coupled plasma (ICP) according to an exemplary embodiment of the present invention.

In FIG. 2, a substrate treatment apparatus 110 using ICP includes a process chamber 112 providing a reaction region by a combination of a lid 112a and a body 112b, a plurality of openings 114 passing through the lid 112a, a plurality of insulating plates 116 respectively sealing the plurality of openings 114, a plurality of antennas 118 respectively disposed the plurality of insulating plates 116, a gas injection unit 124 set up to the lid 112a and the plurality of insulating plates 116, and a substrate holding unit 122 disposed in the reaction region and on which a substrate 120 is placed.

The substrate treatment apparatus 110 may further include a substrate entrance 130, an outlet 132 and an edge frame 134. The substrate 120 is carried into or out of the process chamber 112 through the substrate entrance 130. Reaction gases and by-products in the reaction region are discharged through the outlet 132. The edge frame 134 prevents a thin film from being deposited or being etched on peripheral portions over the substrate 120. The edge frame 134 extends into a portion near by an inner wall of the process chamber 112 from the peripheral portions over the substrate 120. The edge frame 134 keeps an electrically floating state.

The plurality of antennas 118 are connected to a radio frequency (RF) power source 126 in parallel, and a matcher 128 for matching impedance is set up between the plurality of antenna 118 and the RF power source 126. In the substrate treatment apparatus 110, the plurality of antenna, which are supplied with an RF power from the RF power source 126, are used as a plasma source electrode, and the lid 112a and the body 112b, which are grounded, are used as a ground electrode. The lid 112a and the body 112b are formed of a metallic material such as aluminum or stainless steel. The insulating plates 116 are formed of a ceramic material.

The substrate holding unit 122 includes a substrate holding plate 122a and a shaft 122b. The substrate holding plate 122a has a larger size than the substrate 120, and the substrate 120 is disposed on the substrate holding plate 122a. The shaft 122b moves the substrate holding plate 122a upwards and downwards. In the substrate treatment apparatus 110, the substrate holding unit 122 is grounded like the process chamber 112. However, although not shown in the figure, an additional RF power may be applied to the substrate holding unit 122 or the substrate holding unit 122 may be in an electrically floating state according to conditions of a substrate treatment process.

FIG. 3 is a view of enlarging the portion “A” of FIG. 2. In FIG. 3, the opening 114 includes an upper opening part 114a and a lower opening part 114b. The insulating plate 115 is disposed in the upper opening part 114a, and the lower opening part 114b corresponds to a lower surface of the insulating plate 116. The lid 112a includes a protrusion 134 adjacent to the insulating plate 116 and a supporter 136 extending from a lower part of the protrusion 134 and supporting the insulating plate 116. The protrusion 134 and the insulating plate 116 alternate each other. The antenna 118 is spaced apart from and disposed over the insulating plate 116. The antenna 118 includes a flow path 138 for cycling a refrigerant.

The insulating plate 116 is inserted in the upper opening part 114a and is disposed on the supporter 136 with a first O-ring 192a therebewteen. The first O-ring 182a is arranged along peripheries of the insulating plate 116. The insulating plate 116 is fixed by a plurality of fixing means 164 located on the peripheries of the insulating plate 116 and the protrusion 134 adjacent to the insulating plate 116. The plurality of fixing means 164 are set up both peripheries of the insulating plate 116. The fixing means 164 includes a vertical fixing part 164a and a horizontal fixing part 164b. The vertical fixing part 164a contacts an upper surface of the periphery of the insulating plate 116. The horizontal fixing part 164b extends from an upper portion of the vertical part 164a horizontally and is disposed on the protrusion 134. When the horizontal fixing part 164b and the protrusion 135 are combined by a first bolt 184a, a combining pressure is provided to the insulating plate 116 through the vertical fixing part 164a. Accordingly, the insulating plate 116 and the supporter 134 with the first O-ring 182a therebetween can maintain airtightness.

The gas injection unit 124 includes a plurality of first gas injection means 124a and a plurality of second gas injection means 124b. Each first gas injection means 124a is set up at the lid 112a corresponding to the protrusion 134 and provides a first process gas or a first process gas compound. Each second gas injection means 124b is set up at the insulating plate 116 and provides a second process gas or a second process gas compound.

The first gas injection means 124a includes a first sub gas supply line 138a, a first gas incoming line 140a, a first storage portion 142a and a first gas distribution plate 144a. The first sub gas supply line 138a provides the first process gas or the first process gas compound from the outside. The first gas incoming line 140a is connected to the first sub gas supply line 138a and is inserted and set up to the lid 112a corresponding to the protrusion 134. The first storage portion 142a is set up under the first gas incoming line 140a and temporarily storages the first process gas or the first process gas compound. The first gas distribution plate 144a is located under the first storage portion 142a and injects the first process gas or the first process gas compound into the reaction region.

The first sub gas supply line 138a is inserted at a central portion of the protrusion 134. A second O-ring 182b is interposed between a first airtight plate 148a and the protrusion 134, and the first airtight plate 148a and the protrusion 134 are combined by a second bolt 184b so that the first sub gas supply line 138a and the first gas incoming line 140a are connected to each other while maintaining airtightness.

The first gas distribution plate 144a is set up under the first storage portion 142a and includes a plurality of first injection holes 154a. A first depressed portion 156a extending from the first storage portion 142a is formed at the lid 112a. An edge of the first gas distribution plate 144a is disposed in the first depressed portion 156a and is united with the lid 112a by a third bolt 184c.

The first gas incoming line 140a includes an insulating pipe 150 and a connection pipe 152 connected to the insulating pipe 150. Since the lid 112a is formed of a metallic material such as aluminum, plasma can be discharged at a contact point of the first sub gas supply line 138a and the lid 112a. To prevent the discharge of the plasma, the first sub gas supply line 138a is connected to the insulating pipe 150 that is a tube of a ceramic material. The insulating pipe 150 can be extended into the first storage portion 142a. However, since it is enough that the insulating pipe 150 has a size as large as the discharge of the plasma is prevented, it is desirable that the insulating pipe 150 is not extended into the first storage portion 142a for convenience of fabrication.

The second gas injection means 124b includes a second sub gas supply line 138b, a second gas incoming line 140b, a second storage portion 142b and a second gas distribution plate 144b. The second sub gas supply line 138a provides the second process gas or the second process gas compound from the outside. The second gas incoming line 140b is connected to the second sub gas supply line 138b and is set up to an inside of the insulating plate 116. The second storage portion 142b is set up under the second gas incoming line 140b and temporarily storages the second process gas or the second process gas compound. The second gas distribution plate 144b is located under the second storage portion 142b and injects the second process gas or the second process gas compound into the reaction region.

Since the antenna 118 is disposed at the central portion of the insulating plate 116, the second sub gas supply line 138b is inserted at the peripheral portion of the insulating plate 116 spaced apart from the antenna 118. A third O-ring 182c is interposed between a second airtight plate 148b and the insulating plate 116, and the second airtight plate 148b and the insulating plate 116 are combined by a fourth bolt 184d so that the second sub gas supply line 138b and the second gas incoming line 140b are connected to each other while maintaining airtightness. The second gas incoming line 140b includes a first vertical incoming pipe 158, a horizontal incoming pipe 160 and a second vertical incoming pipe 162. The first vertical pipe 158 is connected to the second sub gas supply line 138b. The horizontal incoming pipe 160 is connected to the first vertical incoming pipe 158. The second vertical incoming pipe 162 connects the horizontal incoming pipe 160 and the second storage portion 142b. The second vertical incoming pipe 162 is located at a center of the insulating plate 116.

The insulating plate 116 may be formed by joining a plurality of first ceramic plates having a vertical hole and a plurality of second ceramic plates having a horizontal groove so as to form the first vertical incoming pipe 158, the horizontal incoming pipe 160 and the second vertical incoming pipe 162 in the insulating plate 116. The second gas distribution plate 144b is set up under the second storage portion 142b and includes a plurality of second injection holes 154b. A second depressed portion 156b extending from the second storage portion 142b is formed at the insulating plate 116. An edge of the second gas distribution plate 144b is disposed in the second depressed portion 156b and is united with the insulating plate 116 by a fifth bolt 184e.

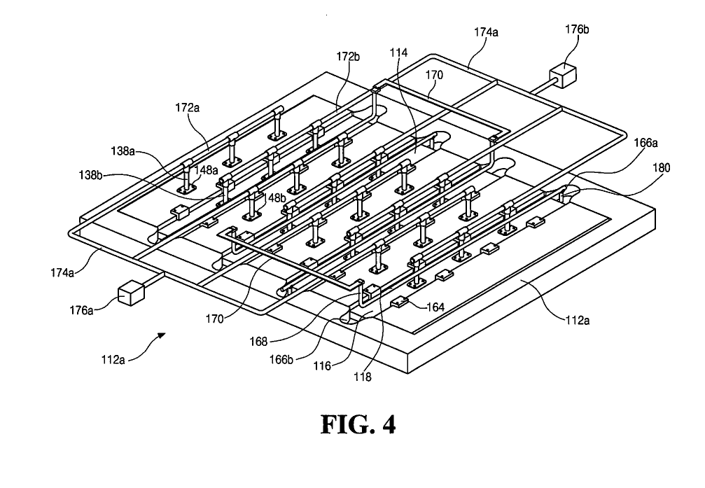

FIG. 4 is a perspective view of an upper part of a lid according to an exemplary embodiment of the present invention. In FIG. 4, the protrusion 134 and the insulating plate 116 each are divided into 3 to 6 sections with a specific interval along a length direction. The first and second gas injection means 124a and 124b of FIG. 2 are set up to the protrusion 134 and the insulating plate 116, respectively.

The plurality of openings 114 pass through the lid 112a and are arranged with a certain interval therebetween in parallel to one another. First and second openings 166a and 166b are formed at both sides of the opening 114 and are extended from the upper opening part 114a of FIG. 3. The first and second openings 166a and 166b do not pass through the lid 112a.

The antenna 118 includes a first end connected to the RF power source 126 of FIG. 2 and a second end grounded. A floating supporter 180 is disposed in the first opening 166a and electrically floats the first end of the antenna 118. A ground connector 168 is disposed in the second opening 166a and electrically grounds the second end of the antenna 118. A plurality of ground connectors 168 respectively connected to the second ends of the plurality of antennas 118 are connected to a ground 170. The first end of each antenna 118 is supported by the floating supporter 180, and the second end of each antenna 118 is held up. Accordingly, the antenna 118 does not contact the insulating plate 116 and is spaced apart from the insulating plate 116.

The first ends of the antennas 118 supported by the floating supporter 180 and the second ends of the antennas 118 connected to the ground connectors 168 are alternately arranged over the lid 112a. At one side of the lid 112a perpendicular to the length direction of the antenna 118k, the first ends of the odd antennas 118 are supported by the floating supporters 180, and at the other side of the lid 112a opposite to the one side, the second ends of the even antennas 118 are connected to the ground 170 through the ground connectors 168. Therefore, the first and second openings 166a and 166b are be switched.

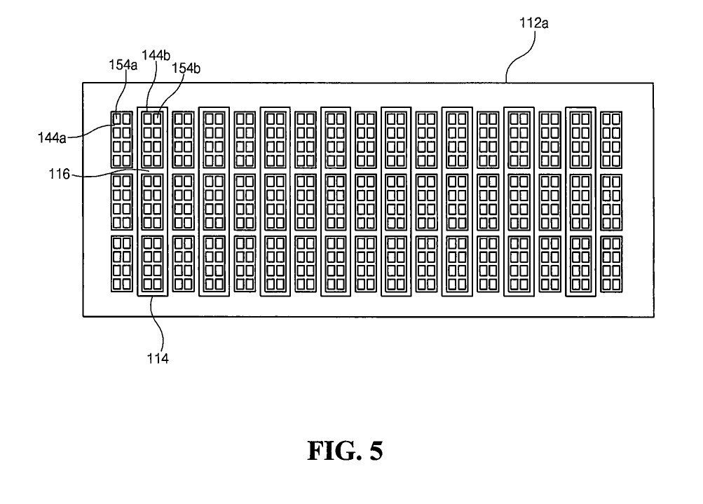

FIG. 5 is a plan view of a lid facing a substrate holder according to an exemplary embodiment of the present invention. The first gas distribution plates 144a of the first gas injection means 124a and the second gas distribution plates 144b of the second gas injection means 124b are uniformly arranged all over the lid 112a, and the process gases can be uniformly provided to the reaction region.

Referring to FIG. 4, a first gas supply line 172a, which provides the first process gas or the first process gas compound, is set up over the protrusion 134 and is connected to the first sub gas supply lines 138a. A plurality of first gas supply lines 172a, which are respectively disposed over the protrusions 134, are connected to a first source unit 176a through a first transporting pipe 174a. A second gas supply line 172b, which provides the second process gas and the second process gas compound, is set up over the insulating plate 116 and is connected to the second sub gas supply lines 138b. A plurality of second gas supply lines 172b, which are respectively disposed over the insulating plates 116, are connected to a second source unit 176b through a second transporting pipe 174b.

In the substrate treatment process of the present invention, the same material can be used as the first and second process gases or the first and second process gas compounds according to necessity. When different materials are used as the first and second process gases or the first and second process gas compounds, the first gas injection means 124a, which is set up at the lid 112a corresponding to the protrusion 135, can inject gases to be activated by plasma, and the second gas injection means 124b, which is set up at the insulating plate 116, can inject gases to be ionized. However, according to necessity, the first gas injection means 124a may inject gases to ionized, and the second gas injection means 124b may inject gases to be activated.

In the ICP type substrate treatment apparatus according to the present invention, the gas injection means are set up at the insulating plate corresponding to the antenna that is used as a plasma source electrode and the lid that is used as a ground electrode, and the process gases can be uniformly supplied to the reaction region. Therefore, a thin film can be uniformly deposited on the substrate or a thin film on the substrate can be uniformly etched.

It will be apparent to those skilled in the art that various modifications and variations can be made in the apparatus without departing from the spirit or scope of the invention. Thus, it is intended that the present invention covers the modifications and variations of this invention provided they come within the scope of the appended claims and their equivalents.

What is claimed is:

1. A substrate treatment apparatus, comprising:
a process chamber providing a reaction region and including a body and a lid, the lid having a plurality of openings;
a plurality of insulating plates sealing the plurality of openings, respectively;
a plurality of antennas over the plurality of insulating plates, respectively;
a gas injection unit over the lid and the plurality of insulating plates; and
a substrate holding unit in the reaction region, wherein a substrate is disposed on the substrate holding unit.

2. The apparatus according to claim 1, wherein the plurality of antennas are used as a plasma source electrode connected to an RF power source, and the lid is used as a plasma ground electrode connected to a ground.

3. The apparatus according to claim 1, wherein each of the plurality of antennas includes a first end and a second end, wherein the first end is connected to an RF power source and the second end is grounded.

4. The apparatus according to claim 1, wherein the lid includes protrusions alternating the plurality of insulating plates and supporters extending from respective lower parts of the protrusions and supporting the plurality of insulating plates.

5. The apparatus according to claim 4, wherein each insulating plate is fixed by a fixing means disposed on the insulating plate and the protrusion adjacent to the insulating plate.

6. The apparatus according to claim 5, wherein the fixing means includes a vertical fixing part and a horizontal fixing part, wherein the vertical fixing part is disposed on the insulating plate, and the horizontal fixing part is extended from an upper portion of the vertical part horizontally, is disposed on the protrusion, and is combined with the protrusion by a bolt.

7. The apparatus according to claim 4, wherein the gas injection unit includes a plurality of first gas injection means and a plurality of second gas injection means, wherein the plurality of first gas injection means are set up at the lid corresponding to the protrusions, and the plurality of second gas injection means are set up at the plurality of insulating plates.

8. The apparatus according to claim 7, wherein each first gas injection means includes:
a sub gas supply line proving a process gas or a process gas compound;
a gas incoming line connected to the sub gas supply line and inserted in the lid corresponding the protrusion;
a storage portion formed in the lid and connected to the gas incoming line; and
a gas distribution plate located under the storage portion and injects the process gas or the process gas compound into the reaction region.

9. The apparatus according to claim 8, wherein the gas incoming line includes an insulating pipe connected to the sub gas supply line and a connection pipe connecting the insulating pipe and the storage portion.

10. The apparatus according to claim 7, wherein each second gas injection means includes:
a sub gas supply line proving a process gas or a process gas compound;
a gas incoming line connected to the sub gas supply line and inserted in the insulating plate;
a storage portion formed in the insulating plate and connected to the gas incoming line; and
a gas distribution plate located under the storage portion and injects the process gas or the process gas compound into the reaction region.

11. The apparatus according to claim 7, wherein the plurality of first gas injection means provide a first process gas or a first process gas compound, and the plurality of second gas injection means provide a second process gas or a second process gas compound.

12. The apparatus according to claim 11, wherein the first process gas or the first process gas compound is a gas to be ionized, and the second process gas or the second process gas compound is a gas to be activated.
